(19) United States
(12) Patent Application Publication
(10) Pub. No.: US 2007/0075314 A1
(43) Pub. Date: Apr. 5, 2007

(54) Low temperature polysilicon thin film transistor display and method of fabricating the same

(75) Inventor: Chia-Tien Peng, Jhubei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/353,435

(22) Filed: Feb. 14, 2006

(30) Foreign Application Priority Data
Sep. 30, 2005 (TW) 94134276

(51) Int. Cl. H01L 29/786; H01L 21/20; H01L 21/84

(52) U.S. Cl. 257/66; 438/486; 438/786; 257/75; 257/632; 438/151

(57) ABSTRACT

A display comprises a substrate, a polysilicon layer which is crystallized by a solid phase crystallization (SPC) method, a gate dielectric layer made of silicon oxy-nitride (SiON) and formed on the polysilicon layer, and a gate electrode formed on the gate dielectric layer (i.e. SiON).

This application claims the benefit of Taiwan application Serial No. 094134276, filed Sep. 30, 2005, the subject matter of which is incorporated herein by reference.

### BACKGROUND OF THE INVENTION

1. Field of the Invention

The invention relates in general to a display and fabricating method, and more particularly to a fabricating method for improving the characteristics of the thin film transistor (TFT) display having poly-silicon transformed by solid phase crystallization (SPC).

2. Description of the Related Art

According to the circuit driving method, the organic light emitting diode display panel can be divided into two groups. One is a passive matrix organic light emitting diode display panel (PMOLED display panel), and the other group is an active matrix organic light emitting diode display panel (AMOLED display panel). The thin film transistor (TFT) and the storage capacitor are used in the AMOLED to control the gray scale performance of the organic light emitting device (OLED).

Generally, the PMOLED has the advantages of low production cost and simple technique, but the inefficient drive current results in the low resolution of the display. Also, the brightness of the lighten pixel of the PMOLED cannot be well maintained. Thus, the PMOLED is usually applied to the product less than 5-inch. On the contrary, the brightness of the lighten pixel of the AMOLED can be well maintained since the storage capacitor is disposed in the AMOLED. Thus, it is no need to drive the OLED to emit the light having high brightness, so that the useful life of the AMOLED is longer than that of the PMOLED. Also, the AMOLED can achieve the requirement of high resolution. Moreover, the circuit drive of the AMOLED is more efficient than that of the PMOLED, and the pixels and TFTs of the AMOLED can be integrated on the glass substrate.

The techniques for manufacturing TFT on the glass substrate include the amorphous silicon (a-Si) process and the low temperature polysilicon (LTPS) process. The major differences between the a-Si process and the LTPS process are the electrical characteristics of devices and the complexity of processes. The LTPS TFT possesses higher mobility, but the process for fabricating the LTPS TFT is more complicated. Although the a-Si TFT possesses higher mobility, the process for fabricating the a-Si TFT is simple.

One of the important procedures for fabricating a low temperature polysilicon (LTPS) thin film transistor (TFT) is the formation of polysilicon. Several methods, including solid phase crystallization (SPC), laser annealing method or metal induced crystallization (MIC), have been suggested to turn the amorphous silicon layer into the polysilicon film. Recently, the laser annealing method is the most common in use. Using the laser annealing method does form the polysilicon film with good mobility, but the expansive production cost and the unstable source of laser beam are the considerable issues for the manufacturers. If an unstable source of laser beam is used for irradiating the amorphous silicon on the display, particularly on the AMOLED display, it would cause the irregular grain size or boundary of the polysilicon, and the image defects (also known as “laser mura”) such as dark spot defects and dark line defects could be shown on the displaying region during displaying; the production yield of display (particularly the AMOLED display) is consequently decreased. In the conventional methods, solid phase crystallization (SPC) is the one perfect method for growing the polysilicon film with regular grain size and boundary. However, the polysilicon film formed by SPC suffers the poor mobility, and is less welcome in the manufacture of the display.

Additionally, the requirements for the regions of a display panel are different. For example, the AMOLED generally comprises a displaying region and a circuit driving region. Whether the current leakage occurs is critical to the displaying region, and the mobility of carriers is a key point of the electrical characteristics of the circuit driving region. Both of the grain size and grain boundary have an effect on the mobility of carriers. Conventionally, the amorphous silicon of the displaying region and the circuit driving region is turned to the polysilicon by an excimer laser beam. However, the polysilicon formed by the excimer laser beam has the irregular grain size and grain boundary, resulting in non-uniform electrical characteristics of the TFTs for driving the displaying region while the operating voltage is applied. Therefore, the image defects such as dark spot defects and dark line defects could be shown on the displaying region during displaying. Typically, the displaying region presents a more uniform image if the polysilicon layer corresponding to the circuit driving region has a larger grain size and more regular grain boundary.

Therefore, it is desirable to form the regular polysilicon grains with good mobility of the display, particular on the displaying region of the display, so as to create no-defect image during displaying.

### SUMMARY OF THE INVENTION

It is therefore an object of the invention to provide a low temperature polysilicon thin film transistor display and method of fabricating the same. Using the polysilicon transformed by solid phase crystallization (SPC) and covered by the silicon oxy-nitride (SiON) layer (as a gate dielectric layer), the electrical characteristics of the display can be greatly improved.

The invention achieves the objects by providing a display comprising a substrate, a polysilicon layer, a silicon oxy-nitride (SiON) layer and a gate electrode. The polysilicon layer is formed on the substrate and crystallized by solid phase crystallization (SPC). The SiON layer is formed on the polysilicon layer, and has a refraction index of about 1.46 to 1.9. The gate electrode is formed on the SiON layer.

The invention achieves the objects by providing a method for fabricating a display, comprising the steps of: providing a substrate; forming an amorphous silicon layer on the substrate; transforming the amorphous silicon layer into a polysilicon layer by solid phase crystallization (SPC); and forming a silicon oxy-nitride (SiON) layer on the polysilicon layer.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a cross-sectional view showing a portion of the thin film transistor according to the embodiment of the invention.

FIG. 2 shows the electrical properties of the P-type thin film transistors.

FIG. 3 shows the electrical properties of the N-type thin film transistors.

FIG. 4 is a cross-sectional view partially showing the thin film transistor according to the first application of the invention.

FIG. 5 is a cross-sectional view partially showing the thin film transistor according to the second application of the invention.

### DETAILED DESCRIPTION OF THE INVENTION

The embodiment disclosed herein is for illustrating the invention, but not for limiting the scope of the invention. Also, the present invention could be applied in the fabrication of many displays, such as an active matrix organic light emitting diode display (AMOLED display), or low temperature polysilicon thin film transistor display (LTPS TFT display). Additionally, the drawings used for illustrating the embodiments of the invention only show the major characteristic parts in order to avoid obscuring the invention. Accordingly, the specification and the drawings are to be regard as an illustrative sense rather than a restrictive sense.

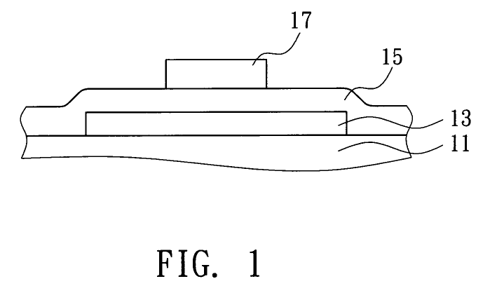

FIG. 1 is a cross-sectional view showing a portion of the thin film transistor according to the embodiment of the invention. First, an amorphous silicon layer is deposited on the substrate 11, and then transformed into a polysilicon layer 13 by solid phase crystallization (SPC). Next, a silicon oxy-nitride (SiON) layer is formed on the polysilicon layer 13 as a gate dielectric layer 15, as shown in FIG. 1. Then, the subsequent processes for fabricating the thin film transistor proceed. For example, a first metal layer can be formed on the gate dielectric layer 15 and then patterned to form the gate electrode 17. Also, refraction index of the silicon oxy-nitride is in a range of about 1.46 to 1.9.

Generally, the substrate of the display comprises a displaying region and a circuit driving region. If the structure of FIG. 1 is applied to the displaying region, the characteristics of the thin film transistor can be improved so as to improve the image quality during displaying since the polysilicon layer 13 formed by SPC has regular grains.

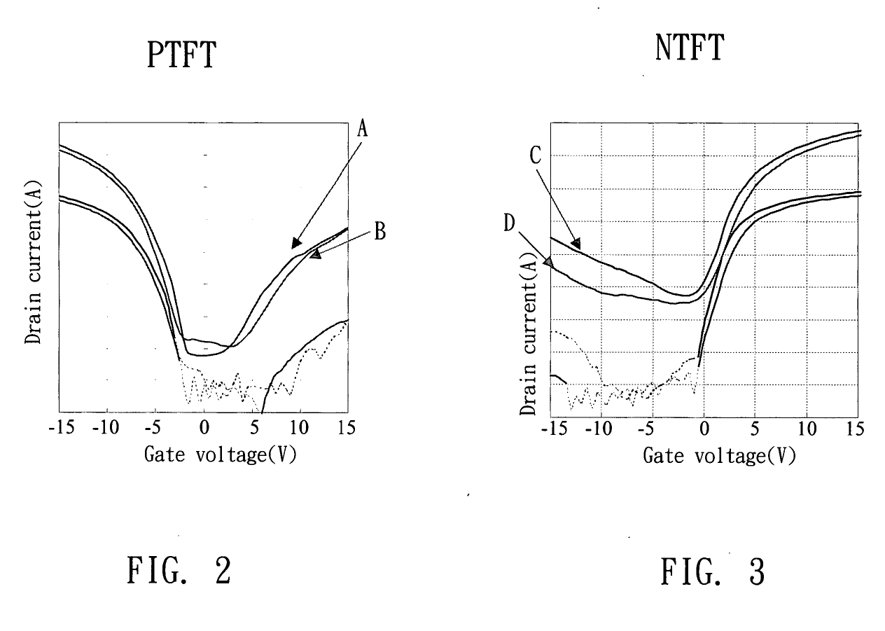

Moreover, the mobility of the thin film transistor is increased by choosing silicon oxy-nitride as the material of the gate dielectric layer 15. Please refer to FIG. 2, which shows the electrical properties of the P-type thin film transistors. The X-coordinate represents the gate voltage (V) and the Y-coordinate represents the drain current (A) (i.e. the electrical charges passing through the drain). The drain voltage is 10 volt. Two different structures are measured in this experiment. Curve A represents the result of electrical property of the structure having a silicon oxy-nitride (SiON) layer as the gate dielectric layer 15 (which is identical to the structure of the embodiment of the invention). Curve B represents the result of electrical property of the structure having silicon oxide (SiO₂) layer as the gate dielectric layer.

The experimental results of FIG. 2 has indicated that the mobility of the structure having the SiON layer (i.e. curve A) is higher than the mobility of the structure having the SiO₂ layer (i.e. curve B), and has an increase of about 70%.

FIG. 3 shows the electrical properties of the N-type thin film transistors. Similarly, the X-coordinate represents the gate voltage (V) and the Y-coordinate represents the drain current (A). Curve C represents the result of electrical property of the structure having the SPC polysilicon layer and a SiON layer as the gate dielectric layer 15. Curve D represents the result of electrical property of the structure having the SPC polysilicon layer and the SiO₂ layer as the gate dielectric layer.

The experimental results of FIG. 3 has also indicated that the mobility of the structure having the SiON layer (i.e. curve C) is higher than the mobility of the structure having the SiO₂ layer (i.e. curve D), and has an increase of about 70%.

In the practical invention, the gate electrode 17 and the gate electrode layer 15 can be patterned at the same procedure, or at different procedures. Two applications are taken for describing the methods of fabricating the thin film transistors. However, it is known that the applications described below are only the exemplified illustrations, and the details of fabrication could be slightly changed, depending on the requirements of the practical conditions.

First Application

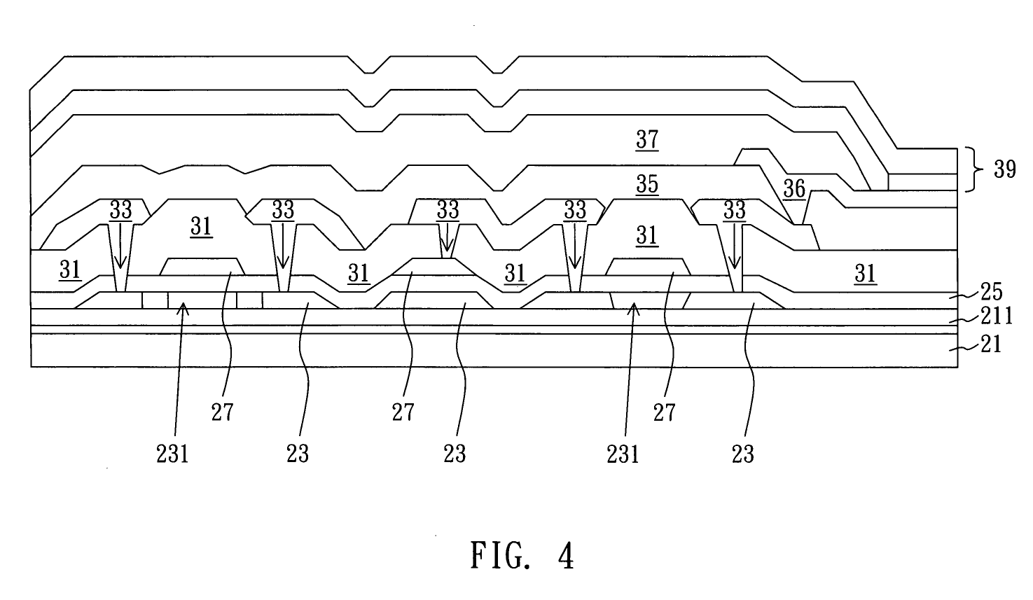

FIG. 4 is a cross-sectional view partially showing the thin film transistor according to the first application of the invention. First, a patterned polysilicon layer 23 is formed on the substrate 21 having a buffer layer 211. For example, an amorphous silicon layer is deposited on the substrate 21, and crystallized by solid phase crystallization (SPC), and then patterned to form the patterned polysilicon layer 23 (including SPC polysilicon 231).

Next, a silicon oxy-nitride (SiON) layer is formed on the patterned polysilicon layer 23 as a gate dielectric layer 25. The refraction index of the SiON layer is in a range of about 1.46 to 1.9. Then, processes for forming the source, drain, lightly doped drain (LDD) and gate electrode 27 are performed.

Afterward, an inter-layer dielectric layer 31 is formed on the gate dielectric layer 25, and several via holes 33 are formed for exposing the surface of the patterned polysilicon layer 23 and the gate electrode 27.

Then, the subsequent processes for fabricating the thin film transistor, including the formations of the data lines, the passivation layers 35, 37, the transparent electrode (e.g. ITO) 36 and the organic electroluminescence device 39, are proceeding.

According to the fabricating method of the first application, the gate electrode 27 is patterned in the former step, and the gate dielectric layer 25 is patterned in the later step. Also, in the thin film transistor fabricated in accordance with the first application of the present invention, the area of the gate electrode 27 is smaller than that of the gate dielectric layer 25.

Second Application

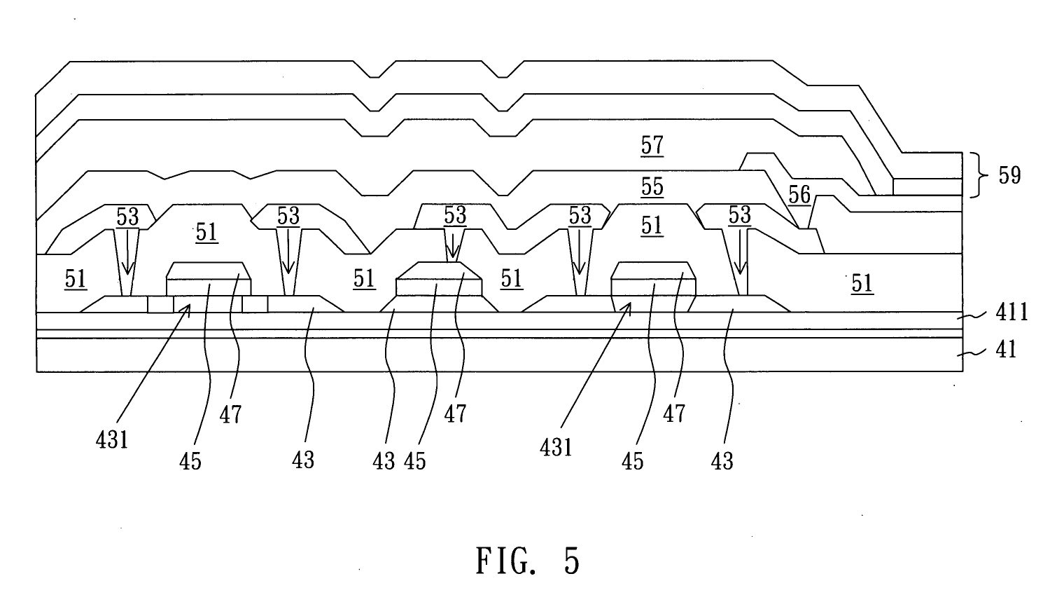

FIG. 5 is a cross-sectional view partially showing the thin film transistor according to the second application of the invention. First, a patterned polysilicon layer 43 is formed on the substrate 41 having a buffer layer 411. For example, an amorphous silicon layer is deposited on the substrate 41, and crystallized by solid phase crystallization (SPC), and then patterned to form the patterned polysilicon layer 43 (including the SPC polysilicon 431).

Next, a silicon oxy-nitride (SiON) layer is formed on the patterned polysilicon layer 43 as a gate dielectric layer 45. The refraction index of the SiON layer is in a range of about 1.46 to 1.9. Then, processes for forming the source, drain, lightly doped drain (LDD) and gate electrode 47 are performed. Also, the gate dielectric layer 45 and the gate electrode 47 are patterned simultaneously in the second application.

Afterward, an inter-layer dielectric (ILD) layer 51 is formed on the patterned polysilicon layer 43, and several via holes 53 are formed for exposing the surface of the patterned polysilicon layer 43 and the gate electrode 47.

Then, the subsequent processes for fabricating the thin film transistor, including the formations of the data lines, the passivation layers 55, 57, the transparent electrode (e.g. ITO) 56 and the organic electroluminescence device 59, are proceeding.

According to the fabricating method of the second application, the gate dielectric layer 45 and the gate electrode 47 are patterned at the same step. Also, in the thin film transistor fabricated in accordance with the second application of the present invention, the area of the gate electrode 27 is identical to that of the gate dielectric layer 25.

According to the aforementioned descriptions, the combination, which chooses the polysilicon layer crystallized by the SPC and the SiON layer as the gate dielectric layer, not only obtain the polysilicon grains with regular size and good quality but also increase the mobility of the applied device such as the thin film transistor. Therefore, the electrical characteristics of the applied device is improved, the throughput is increased, and the production cost is decreased by applying the present invention. If the displaying region of the applied device comprises the structure of the present invention, an image with excellent quality can be clearly shown during displaying.

While the invention has been described by way of examples and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display, comprising:
a substrate;
a polysilicon layer formed on the substrate and crystallized by solid phase crystallization (SPC);
a silicon oxy-nitride (SiON) layer formed on the polysilicon layer; and
a gate electrode formed on the SiON layer.

2. The display according to claim 1, wherein a refraction index of the SiON layer is in a range of about 1.46 to 1.9.

3. The display according to claim 1, wherein the substrate comprises a displaying region and a circuit driving region, the polysilicon layer has a first polysilicon portion corresponding to the displaying region and a second polysilicon portion corresponding to the circuit driving region, while the first polysilicon portion is crystallized by SPC.

4. The display according to claim 3, wherein the SiON layer is formed on the first polysilicon portion.

5. The display according to claim 1 is a low temperature polysilicon thin film transistor (LTPS TFT) display.

6. A method for fabricating a polysilicon layer for use in a display, comprising the steps of:
providing a substrate;
forming an amorphous silicon layer on the substrate;
transforming the amorphous silicon layer into a polysilicon layer by solid phase crystallization (SPC); and
forming a silicon oxy-nitride (SiON) layer on the polysilicon layer.

7. A method for fabricating a display, comprising the steps of:
providing a substrate having a displaying region and a circuit driving region;
forming an amorphous silicon layer having a first amorphous silicon portion and a second amorphous silicon portion on the substrate, so that the first and the second amorphous silicon portions correspond to the displaying region and the circuit driving region, respectively;
transforming the first amorphous silicon portion into a first polysilicon portion by solid phase crystallization (SPC); and
forming a silicon oxy-nitride (SiON) layer on the first polysilicon portion.

8. The method according to claim 7, further comprising:
forming a first metal layer on the SiON layer; and
patterning the first metal layer and the SiON layer to form a gate electrode on a SiON block.

9. The method according to claim 7, further comprising:
forming a first metal layer on the SiON layer; and
patterning the first metal layer to form a gate electrode on the SiON layer.

10. The method according to claim 7, wherein the SiON layer having a refraction index of about 1.46 to 1.9 is formed on the first polysilicon portion.
